(19) United States
(12) Patent Application Publication
(10) Pub. No.: US 2024/0282903 A1
(43) Pub. Date: Aug. 22, 2024

(54) DISPLAY PANEL, DISPLAY PANEL SUBASSEMBLY AND DISPLAY APPARATUS

(71) Applicants: BOE MLED Technology Co., Ltd., Beijing (CN); BOE TECHNOLOGY GROUP CO., LTD., Beijing (CN)

(72) Inventors: Shaofei GUO, Beijing (CN); Ping LI, Beijing (CN); Shipeng WANG, Beijing (CN); Bo GAO, Beijing (CN); Chao TIAN, Beijing (CN); Xuehai QIAN, Beijing (CN); Xiaozhou LIU, Beijing (CN); Baoxin ZHANG, Beijing (CN); Qian ZHANG, Beijing (CN)

(21) Appl. No.: 18/613,195

(22) Filed: Mar. 22, 2024

Related U.S. Application Data
(63) Continuation of application No. PCT/CN2023/077487, filed on Feb. 21, 2023.

(51) Int. Cl. H01L 33/64; H01L 23/498; H01L 23/538; H01L 25/16

(52) U.S. Cl. CPC H01L 33/644; H01L 23/4985; H01L 23/5387; H01L 25/167; H01L 33/641

(57) ABSTRACT

The present disclosure provides a display panel, including: a drive substrate; a plurality of light-emitting elements on one side of the drive substrate; a functional assembly on a side of the drive substrate away from the light-emitting elements and connected to the drive substrate; where in a direction parallel to a plane where the drive substrate is located, the functional assembly has a heat conductivity higher than the drive substrate. An embodiment of the present disclosure further provides a display panel subassembly and a display apparatus.

### TECHNICAL FIELD

The present disclosure relates to the field of display, and particularly relates to a display panel, a display panel subassembly, and a display apparatus.

### BACKGROUND

A large display screen is typically formed by a plurality of display panel subassemblies spliced in array, and display images of the display panel subassemblies are combined into a complete image on the large display screen. Each display panel subassembly includes a fixing frame and at least one display panel on the fixing frame. The display panel includes a drive substrate and a plurality of light-emitting elements (i.e., light-emitting diodes) on the drive substrate.

It is found in practical applications that in operation of the display panel, part of the electrical structures (e.g., light-emitting elements, flexible printed circuits, etc.) therein will generate heat, causing non-uniform temperature distribution over the display panel. Further, since the light-emitting elements differ greatly in the luminous efficiency at different temperatures, the problem of notable color shift in at partial region of the display panel may occur.

### SUMMARY

In a first aspect, an embodiment of the present disclosure provides a display panel, including:
a drive substrate;
a plurality of light-emitting elements on one side of the drive substrate;
a functional assembly on a side of the drive substrate away from the light-emitting elements and connected to the drive substrate; wherein
in a direction parallel to a plane where the drive substrate is located, the functional assembly has a heat conductivity higher than the drive substrate.

In some embodiments, the drive substrate includes: a base substrate, and a plurality of driver circuits on the base substrate, wherein the light-emitting elements are connected to the corresponding driver circuits; and
in a direction parallel to a plane where the base substrate is located, the functional assembly has a heat conductivity higher than the base substrate.

In some embodiments, the functional assembly includes: at least one graphite sheet.

In some embodiments, a side surface of the drive substrate away from the light-emitting elements has: a first central region, and a first peripheral region surrounding the first central region, wherein the first peripheral region includes: at least one bonding region provided with a plurality of bonding terminals;
the display panel further includes: at least one flexible printed circuit, wherein the flexible printed circuit includes: a first conductive connection part, a line part, and a second conductive connection part, wherein the line part is located between the first conductive connection part and the second conductive connection part, and the first conductive connection part is connected to a corresponding bonding terminal on the drive substrate; and
the at least one graphite sheet includes: a first graphite sheet and/or second graphite sheet; wherein
the first graphite sheet is located on a side of the line part of the flexible printed circuit close to the drive substrate, an orthographic projection of the first graphite sheet on the drive substrate covers the first central region and is not overlapped with the bonding region, and the second conductive connection part of each flexible printed circuit is located on a side of the first graphite sheet away from the drive substrate; and
the second graphite sheet is located on a side of the first conductive connection part away from the drive substrate, an orthographic projection of the second graphite sheet on the drive substrate covers the bonding region and at least part of the first central region, at least part of the line part of the at least one flexible printed circuit is located between the second graphite sheet and the drive substrate, and the second conductive connection part of each flexible printed circuit is located on a side of the second graphite sheet away from the drive substrate.

In some embodiments, a ground signal end is provided on the line part of the at least one flexible printed circuit;
a first conductive film is provided between the first graphite sheet and the line part of the flexible printed circuit, and the first conductive film is electrically connected to the ground signal end of the at least one flexible printed circuit;
and/or
a second conductive film is provided on a side of the second graphite sheet away from the drive substrate, and the second conductive film is electrically connected to the ground signal end of the at least one flexible printed circuit.

In some embodiments, the first conductive film is provided between the first graphite sheet and the line part of the flexible printed circuit;
a portion of the first graphite sheet is connected to the second graphite sheet through the first conductive film; and
in a direction perpendicular to the plane where the drive substrate is located, the first conductive film has a heat conductivity higher than the first graphite sheet and the second graphite sheet.

In some embodiments, the orthographic projection of the second graphite sheet on the drive substrate covers the orthographic projection of the first graphite sheet on the drive substrate.

In some embodiments, the at least one flexible printed circuit includes: at least one first flexible printed circuit and at least one second flexible printed circuit, wherein a line part of the first flexible printed circuit is provided with a chip, while a line part of the second flexible printed circuit is not provided with a chip; and
at least part of the line part of the second flexible printed circuit is located between the first graphite sheet and the second graphite sheet, and the line part of the first flexible printed circuit is located on a side of the second graphite sheet away from the first graphite sheet.

In some embodiments, the at least one graphite sheet further includes: a third graphite sheet; wherein
the third graphite sheet is located on a side of the line part of the first flexible printed circuit away from the drive substrate, and the third graphite sheet includes a first portion and a second portion connected with each other, and
the first portion of the third graphite sheet covers at least partially a side surface of the line part of the first flexible printed circuit away from the drive substrate, and the second portion of the third graphite sheet is connected to the second graphite sheet.

In some embodiments, the at least one flexible printed circuit includes: at least one first flexible printed circuit provided with a chip on a line part;
a thermal insulation structure corresponding to the chip is provided on a side surface of the line part of the first flexible printed circuit facing the drive substrate, and an orthographic projection of the thermal insulation structure on the line part of the first flexible printed circuit is overlapped with an orthographic projection of the corresponding chip on the line part of the first flexible printed circuit.

In a second aspect, an embodiment of the present disclosure provides a display panel subassembly, including: a fixing frame, and at least one display panel as described in the first aspect; wherein
the fixing frame is configured to bear the display panel.

In some embodiments, the fixing frame includes at least one bearing region corresponding to the at least one display panel one by one, the display panel is located in the corresponding bearing region, and the bearing region includes: a second central region, and a second peripheral region surrounding the second central region;
at least a portion of the fixing frame in the second peripheral region is connected to the corresponding display panel through a corresponding first connection structure, and at least a portion of the fixing frame in the second peripheral region is connected to the corresponding display panel through a corresponding second connection structure; and
in a direction perpendicular to a plane where the drive substrate is located, the second connection structure has a heat conductivity higher than the first connection structure.

In some embodiments, an orthographic projection of the second connection structure on the drive substrate covers the bonding region.

In some embodiments, the fixing frame includes a bottom plate and a first support structure on a side of the bottom plate facing the display panel, wherein the first support structure is located in the second peripheral region;
the first support structure is connected to the display panel through the first connection structure; and
at least a portion of the bottom plate in the second central region is connected to the display panel through the second connection structure.

In some embodiments, the fixing frame further includes: a second support structure on a side of the bottom plate facing the display panel, wherein the second support structure is connected to the display panel through a third connection structure; and
in the direction perpendicular to the plane where the drive substrate is located, the third connection structure has a heat conductivity higher than or equal to the first connection structure.

In some embodiments, the third connection structure includes: a thermal conductive tape.

In some embodiments, the first support structure, the second support structure and the bottom plate enclose at least one receiving recess in the second central region, wherein the at least one receiving recess is provided with the second connection structure.

In some embodiments, the first connection structure includes: a thermal insulation tape or a thermal conductive tape; and
the second connection structure includes: a thermal conductive adhesive.

In some embodiments, the thermal conductive adhesive has a thickness of 0.2 mm to 0.7 mm.

In a third aspect, an embodiment of the present disclosure further provides a splicing display apparatus, including: a bearing box and a plurality of display panel subassemblies; wherein
the bearing box is configured to bear the plurality of the display panel subassemblies; and
at least one of the display panel subassemblies is the display panel subassembly according to the second aspect.

### BRIEF DESCRIPTION OF DRAWINGS

FIG. 1 is a schematic structural diagram of a display panel according to an embodiment of the present disclosure;

FIG. 2 is a schematic top view of a drive substrate without a functional assembly on a side away from light-emitting elements according to an embodiment of the present disclosure;

FIG. 3A is a schematic top view of a drive substrate provided with a first graphite sheet on a side away from light-emitting elements according to an embodiment of the present disclosure;

FIG. 3B is a schematic top view of a drive substrate provided with a second graphite sheet on a side away from light-emitting elements according to an embodiment of the present disclosure;

FIG. 4 is a schematic top view of a drive substrate provided with both a first graphite sheet and a second graphite sheet on a side away from light-emitting elements according to an embodiment of the present disclosure;

FIG. 5A is a schematic sectional view taken along line A-A′ of FIG. 4;

FIG. 5B is another schematic sectional view taken along line A-A′ of FIG. 4;

FIG. 6 is a schematic top view of a drive substrate provided with a first graphite sheet, a second graphite sheet, and a third graphite sheet on a side away from light-emitting elements according to an embodiment of the present disclosure;

FIG. 7A is a schematic sectional view taken along line B-B′ of FIG. 6;

FIG. 7B is another schematic sectional view taken along line B-B′ of FIG. 6;

FIG. 8A is a schematic structural diagram of a thermal insulation structure on a first flexible printed circuit according to an embodiment of the present disclosure;

FIG. 8B is another schematic structural diagram of a thermal insulation structure on a first flexible printed circuit according to an embodiment of the present disclosure;

FIG. 9 is a schematic structural diagram of a display panel subassembly according to an embodiment of the present disclosure;

FIG. 10A is a schematic top view of a fixing frame according to an embodiment of the present disclosure;

FIG. 10B is a schematic sectional view taken along line D-D′ of FIG. 10A;

FIG. 11A is a schematic top view of a fixing frame according to an embodiment of the present disclosure;

FIG. 11B is a schematic sectional view taken along line E-E′ of FIG. 11A; and

FIG. 12 is a schematic structural diagram of a splicing display apparatus according to an embodiment of the present disclosure.

### DETAIL DESCRIPTION OF EMBODIMENTS

To make those skilled in the art better understand the technical solutions of the present disclosure, the display panel, the display panel subassembly, and the display apparatus provided in the present disclosure will be described below in detail in conjunction with the accompanying drawings.

The present disclosure will be described in detail below with reference to the accompanying drawings. Throughout the drawings, elements the same as or similar to each other are indicated by similar reference signs. For the sake of clarity, various parts in the figures are not all drawn to scale. Moreover, some well-known parts may not be shown in the figures.

For better understanding of the present disclosure, many specific details, such as structures, materials, dimensions, processing, and techniques of components, of the present disclosure are described below. However, the present disclosure may be implemented without these specific details, as will be understood by those skilled in the art.

The words “first”, “second” and similar terms used in the embodiments of the present disclosure do not denote any order, quantity, or importance, but are used merely for distinguishing different components from each other. Likewise, the word “comprising” or “including” or the like means that the element or item preceding the word contains elements or items that appear after the word or equivalents thereof, but does not exclude other elements or items.

In the embodiments of the present disclosure, the reference to two structures “connected” or “coupled” together or the like refer to not only the two structures connected by directly contacting each other, but also the two structures indirectly connected through other structures. In addition, as used herein, the reference to two structures “fixed” together merely indicates that the two structures are not separable under a certain condition or at a certain moment, but may be separable under other conditions or at other moments.

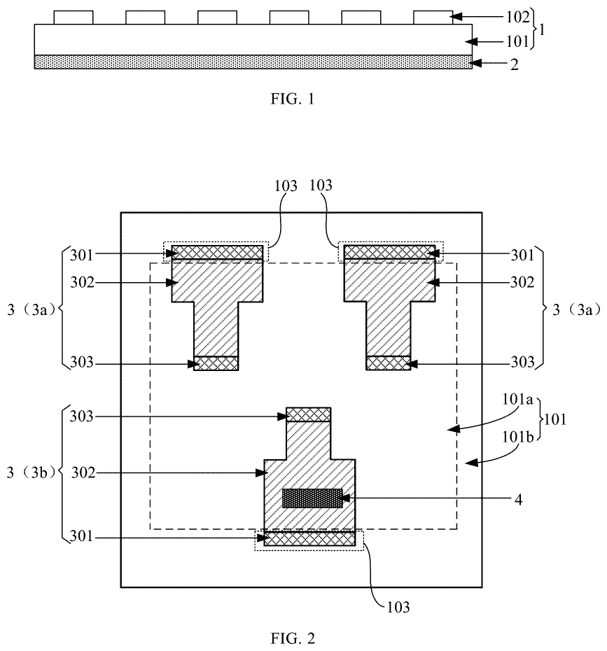

FIG. 1 is a schematic structural diagram of a display panel according to an embodiment of the present disclosure. As shown in FIG. 1, the display panel includes: a light-emitting substrate 1 and a functional assembly 2. The light-emitting substrate includes: a drive substrate 101 and a plurality of light-emitting elements 102. The light-emitting elements 102 are located on one side of the drive substrate 101. The functional assembly 2 is located on a side of the drive substrate 101 away from the light-emitting elements 102 and connected to the drive substrate 101. In a direction parallel to a plane where the drive substrate 101 is located, the functional assembly 2 has a heat conductivity higher than the drive substrate 101.

In the embodiments of the present disclosure, the functional assembly 2 can effectively transfer heat from a high temperature region on the drive substrate 101 to a low temperature region in a direction parallel to the drive substrate 101, so that a temperature difference between the high temperature region and the low temperature region is reduced, which is beneficial to uniform temperature distribution on the display panel, and can further effectively improve the color shift problem caused by a large temperature difference.

It should be understood by those skilled in the art that as long as the functional assembly 2 connected to the drive substrate 101 is disposed on a side of the drive substrate 101 facing away from the light-emitting elements 102, the functional assembly 2 can allow the heat of the region of the drive substrate 101 covered thereby to be uniform, thereby facilitating the uniform temperature distribution over the corresponding region. In practical applications, a specific position of the drive substrate 101 covered by the functional assembly 2 may be preset and adjusted according to the temperature distribution over the drive substrate 101 when the functional assembly 2 is not provided, which is not limited in the present disclosure. Exemplary description is given below in connection with some examples.

In some embodiments, the light-emitting element 102 in the present disclosure may be a micro LED or a mini LED. The micro LED or mini LED can be mounted on a first side (generally referred to as a front side) of the drive substrate 101 through a die bonding process. On a second side (generally referred to as a back side) of the drive substrate 101, a flexible printed circuit (FPC) 3 may be provided and configured to supply an electrical signal to the light-emitting element 102 on the first side to drive the light-emitting element 102 to emit light.

In the embodiments of the present disclosure, for convenience of description, a direction parallel to the plane where the drive substrate 101 is located is referred to as a “lateral direction”, and a direction perpendicular to the plane where the drive substrate 101 is located is referred to as a “longitudinal direction”.

In some embodiments, the drive substrate 101 includes: a base substrate, and driver circuits on the base substrate. The light-emitting elements 102 are connected to the corresponding driver circuits. In a direction parallel to a plane where the base substrate is located, the functional assembly 2 has a heat conductivity higher than the base substrate.

The base substrate may be made of glass. Apparently, the base substrate may also be made of plastic, quartz, metal, or other materials. In this case, the driver circuit may include signal trace(s), transistor(s), or any other circuit structure on one side of the base substrate for driving the light-emitting elements to light.

In addition, the base substrate may be an FR4 type printed circuit board composed of an insulation board, a connection wiring layer, and a pad for assembling and soldering an electronic component (e.g., a light-emitting element, a drive element, a sensor element, etc.). The insulation board and the connection wiring layer may each have multiple layers. Connection wires in different layers may be connected through holes provided in the insulation board. In this case, the driver circuit may include a micro driver chip.

In some embodiments, the base substrate is a glass substrate. Generally, the glass substrate has a heat conductivity lower than or approximately equal to 1 W/(m·K) in the lateral direction. Therefore, the provided functional assembly 2 may have a heat conductivity higher than 1 W/(m·K) in the lateral direction.

In some embodiments, the functional assembly 2 includes: at least one graphite sheet. The graphite sheet has a heat conductivity of about 151 W/(m·K) in a direction perpendicular to a thickness direction of the graphite sheet, which means that the graphite sheet has better thermal conductive performance in the direction perpendicular to the thickness direction of the graphite sheet. Therefore, when the graphite sheet is adhered to the side surface of the glass substrate away from the light-emitting elements 102, the thermal conductive performance of the whole display panel in the lateral direction can be improved.

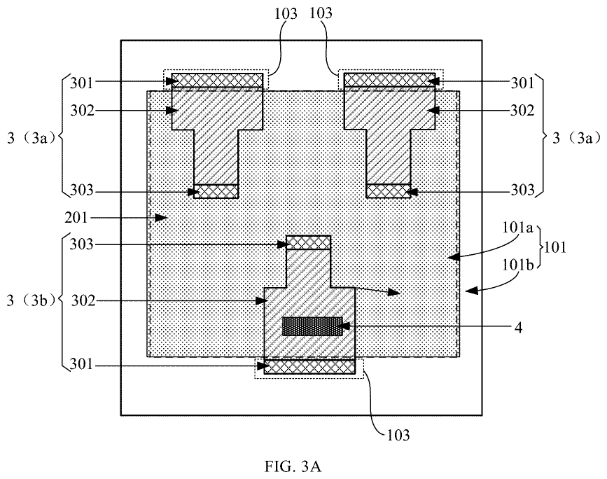

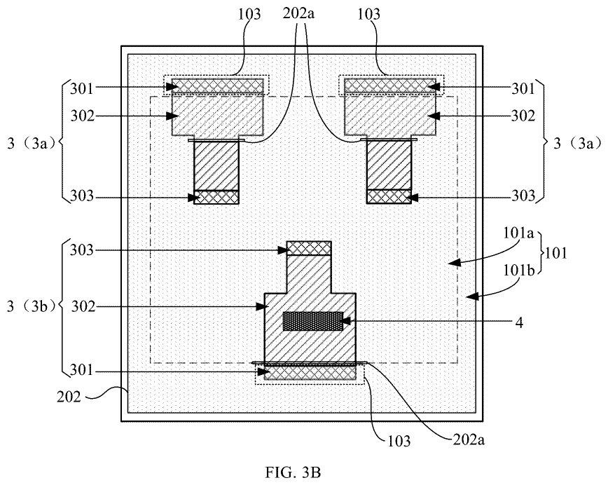

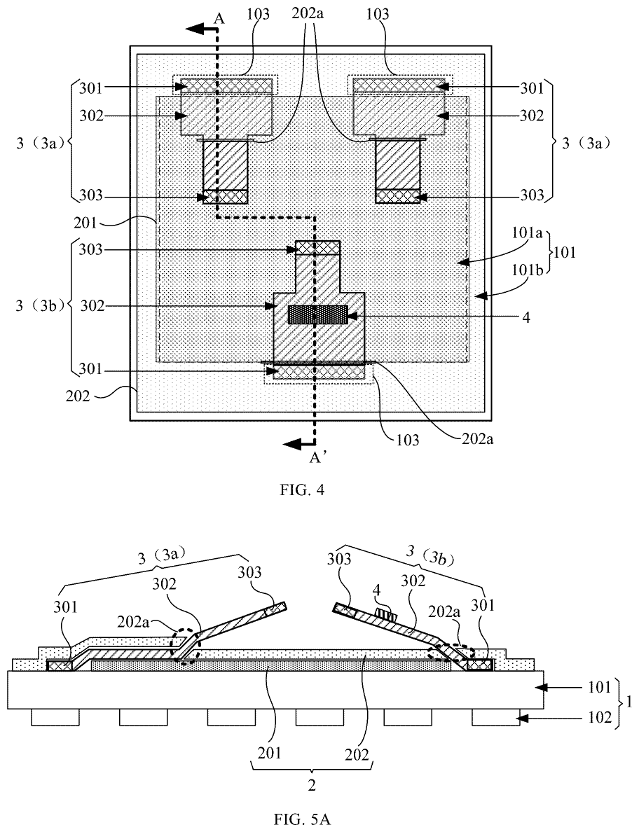

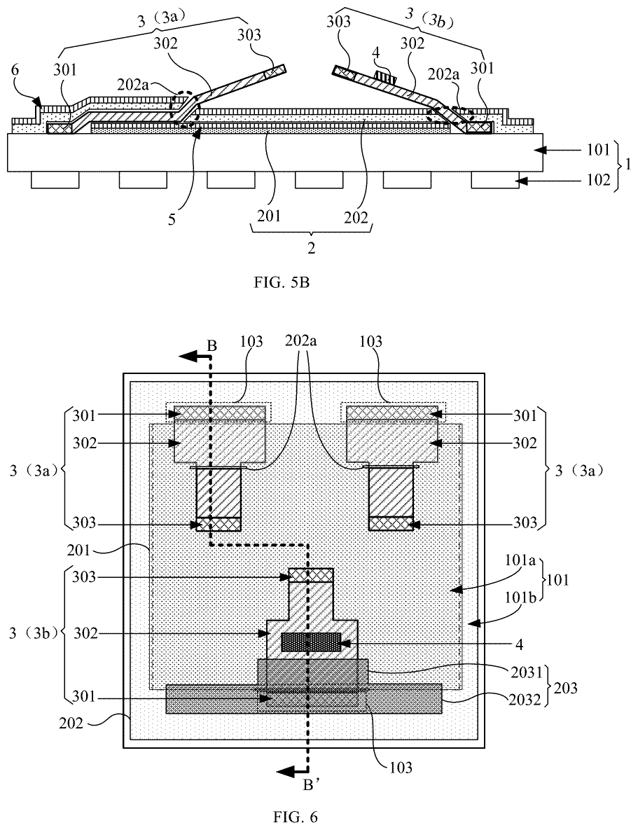

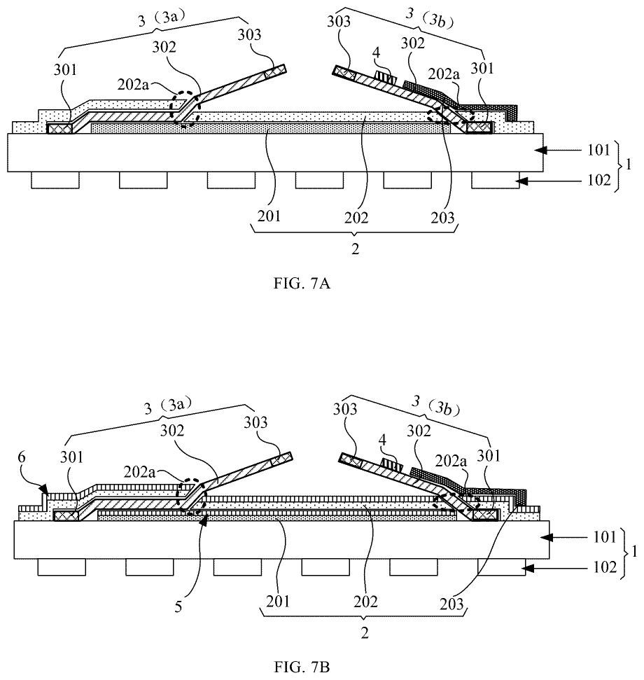

FIG. 2 is a schematic top view of a drive substrate without a functional assembly on a side away from light-emitting elements according to an embodiment of the present disclosure. FIG. 3A is a schematic top view of a drive substrate provided with a first graphite sheet on a side away from light-emitting elements according to an embodiment of the present disclosure. FIG. 3B is a schematic top view of a drive substrate provided with a second graphite sheet on a side away from light-emitting elements according to an embodiment of the present disclosure. FIG. 4 is a schematic top view of a drive substrate provided with both a first graphite sheet and a second graphite sheet on a side away from light-emitting elements according to an embodiment of the present disclosure. FIG. 5A is a schematic sectional view taken along line A-A′ of FIG. 4, and FIG. 5B is another schematic sectional view taken along line A-A′ of FIG. 4. FIG. 6 is a schematic top view of a drive substrate provided with a first graphite sheet, a second graphite sheet, and a third graphite sheet on a side away from light-emitting elements according to an embodiment of the present disclosure. FIG. 7A is a schematic sectional view taken along line B-B′ of FIG. 6. FIG. 7B is another schematic sectional view taken along line B-B′ of FIG. 6. As shown in FIGS. 2 to 7, in some embodiments, a side surface of the drive substrate 101 away from the light-emitting elements 102 has: a first central region 101a, and a first peripheral region 101b surrounding the first central region 101a. The first peripheral region 101b includes: at least one bonding region 103 provided with a plurality of bonding terminals. The display panel further includes: at least one flexible printed circuit 3. The flexible printed circuit 3 includes: a first conductive connection part 301, a line part 302, and a second conductive connection part 303. The line part 302 is located between the first conductive connection part 301 and the second conductive connection part 303, and the first conductive connection part 301 is connected to a corresponding bonding terminal on the drive substrate 101.

The at least one graphite sheet includes: at least one of a first graphite sheet 201 or a second graphite sheet 202. The first graphite sheet 201 is located on a side of the line part 302 of the flexible printed circuit 3 close to the drive substrate 101. An orthographic projection of the first graphite sheet 201 on the drive substrate 101 covers the first central region 101a and is not overlapped with the bonding region 103. The second conductive connection part 303 of each flexible printed circuit 3 is located on a side of the first graphite sheet 201 away from the drive substrate 101. The second graphite sheet 202 is located on a side of the first conductive connection part 301 away from the drive substrate 101. An orthographic projection of the second graphite sheet 202 on the drive substrate 101 covers the bonding region 103 and at least part of the first central region 101a. At least part of the line part 302 of the at least one flexible printed circuit 3 is located between the second graphite sheet 202 and the drive substrate 101. The second conductive connection part 303 of each flexible printed circuit 3 is located on a side of the second graphite sheet 202 away from the drive substrate 101.

It should be noted that when the second graphite sheet 202 is provided, an opening 202a may be provided in the second graphite sheet 202, to enable the second conductive connection part 303 of each flexible printed circuit 3 to pass through the opening in the second graphite sheet 202 and extend to a side of the second graphite sheet 202 away from the drive substrate 101, so that the second conductive connection part 303 can be connected to a circuit board (not shown) later.

In an embodiments of the present disclosure, considering that non-uniform temperature distribution tends to occur in the central region of the display panel in the existing art, making the problem of color shift due to the non-uniform temperature easy to be generated in the central region of the display panel, the first graphite sheet 201 in an embodiment of the present disclosure is provided to cover the first central region 101a of the drive substrate 101, so as to effectively improve the temperature uniformity in the first central region 101a.

In addition, in a bonding region 103 where the flexible printed circuit 3 is bonded to the drive substrate 101, the temperature is also notably higher, and thus the heat is required to be uniform in the lateral direction on the bonding region 103 of the drive substrate 101. Therefore, in the embodiments of the present disclosure, by disposing the second graphite sheet 202 to cover the bonding region 103 of the drive substrate 101 and at least part of the first central region 101a, the temperature uniformity in at least part of the first central region 101a and in the bonding region 103 can be effectively improved.

In the embodiments of the present disclosure, the uniform temperature distribution over the display panel can be facilitated to some extent by disposing only the first graphite sheet 201 (shown in FIG. 3A), only the second graphite sheet 202 (shown in FIG. 3B), or both the first graphite sheet 201 and the second graphite sheet 202 (shown in FIG. 4).

Referring to FIG. 4, in some embodiments, an orthographic projection of the second graphite sheet 202 on the drive substrate 101 covers the orthographic projection of the first graphite sheet 201 on the drive substrate 101. In this case, the first central region 101a of the drive substrate 101 is provided with both the first graphite sheet 201 and the second graphite sheet 202, while the peripheral region of the drive substrate 101 is provided with only the second graphite sheet 202. In this case, a portion of the functional assembly in the first central region 101a as a whole has better thermal conductive performance in the lateral direction than a portion of the functional assembly in the first peripheral region 101b as a whole, so as to cope with the defect that the central region of the display panel generally has a higher temperature than the peripheral region in the existing art.

Referring to FIGS. 5B and 7B, in some embodiments, a ground signal end (not shown) is provided on the line part 302 of the at least one flexible printed circuit 3. The at least one graphite sheet includes a first graphite sheet 201. A first conductive film 5 is provided between the first graphite sheet 201 and the line part 302 of the flexible printed circuit 3, and electrically connected to the ground signal end of the at least one flexible printed circuit 3.

In some embodiments, the at least one graphite sheet includes a second graphite sheet 202. A second conductive film 6 is provided on a side of the second graphite sheet 202 away from the drive substrate 101, and electrically connected to the ground signal end of the at least one flexible printed circuit 3.

In the embodiments of the present disclosure, by providing at least one of the first conductive film 5 or the second conductive film 6, and electrically connecting at least one of the first conductive film 5 or the second conductive film 6 to a ground signal end of the flexible printed circuit 3, a ground signal is loaded onto at least one of the first conductive film 5 or the second conductive film 6, thereby effectively improving the overall electro-static discharge (ESD) precaution and electromagnetic interference (EMI) resistance capabilities of the display panel.

As one example, if there is no graphite sheet between the first/second conductive films 5, 6 and the ground signal end to be connected, the first/second conductive films 5, 6 may be directly connected to the corresponding ground signal end by a conductive adhesive. As another example, if there is a graphite sheet between the first/second conductive films 5, 6 and the ground signal end to be connected, a hole may be defined in the graphite sheet and filled with a conductive adhesive, so that the conductive adhesive in the hole is connected to both the first/second conductive films 5, 6 and the corresponding ground signal end. As another example, one of the first conductive film 5 or the second conductive film 6 may be connected to the ground signal end, and then a hole is defined in the second graphite sheet 202 and filled with a conductive adhesive, so that the conductive adhesive in the hole is connected to both the first conductive films 5 and the second conductive film 6, thereby implementing the electrical connection between both of the first conductive film 5 and the second conductive film 6 and the ground signal end. It should be noted that, in the embodiments of the present disclosure, which flexible printed circuit 3 has the ground signal end electrically connected to the first conductive film 5 and the second conductive film 6, and how to implement the electrical connection are not limited in the present disclosure.

In some embodiments, the at least one graphite sheet includes both the first graphite sheet 201 and the second graphite sheet 202. A first conductive film 5 is provided between the first graphite sheet 201 and the line part 302 of the flexible printed circuit 3. A portion of the first graphite sheet 201 is connected to the second graphite sheet 202 through the first conductive film 5. In a direction perpendicular to the plane where the drive substrate 101 is located, the first conductive film 5 has a heat conductivity higher than the first graphite sheet 201 and the second graphite sheet 202.

In an embodiments of the present disclosure, when the first graphite sheet 201 and the second graphite sheet 202 are both provided, since the graphite sheets have poorer thermal conductive performance in the longitudinal direction, the first graphite sheet 201 transfers heat to the second graphite sheet 202 with a low heat conduction efficiency, making it difficult to sufficiently exert the thermal conductive performance of the second graphite sheet 202 in the lateral direction.

To improve the above problem, in the present disclosure, the first conductive film 5 between the first graphite sheet 201 and the second graphite sheet 202 is designed to have a heat conductivity in the longitudinal direction, so as to improve the heat conduction efficiency of the first graphite sheet 201 transferring heat to the second graphite sheet 202. In this case, the three-layer structure formed by the first graphite sheet 201, the first conductive film 5 and the second graphite sheet 202 has better thermal conductive performance in both the lateral direction and the longitudinal direction, which is beneficial to achieving better heat uniformity. In some embodiments, the first conductive film 5 includes copper foil, which has not only a better conductivity, but also better thermal conductive performance in a direction perpendicular to a thickness direction thereof.

Apparently, it is also possible to set that the second conductive film 6 has a higher heat conductivity in the longitudinal direction than the second graphite sheet 202, which can also improve the heat uniformity of the second graphite sheet 202 to some extent. In some embodiments, the second conductive film 6 includes copper foil.

In some embodiments, the at least one flexible printed circuit 3 includes: at least one first flexible printed circuit 3b and at least one second flexible printed circuit 3a. A line part 302 of the first flexible printed circuit 3b is provided with a chip 4, while a line part 302 of the second flexible printed circuit 3a is not provided with a chip 4. In other words, the chip 4 is packaged on the line part 302 of the first flexible printed circuit 3b through a chip on film process.

The at least one graphite sheet includes a first graphite sheet 201 and a second graphite sheet 202. At least part of the line part 302 of the second flexible printed circuit 3a is located between the first graphite sheet 201 and the second graphite sheet 202. The line part 302 of the first flexible printed circuit 3b is located on a side of the second graphite sheet 202 away from the first graphite sheet 201.

In some embodiments, the first flexible printed circuit 3b is a flexible printed circuit 3 provided with a source driver chip 4, and may be specifically a flexible printed circuit 3 for data driving (data FPC). The second flexible printed circuit 3a is a flexible printed circuit 3 for power supply (power FPC). The drawings merely exemplarily show the display panel including one first flexible printed circuit 3b and two second flexible printed circuits 3a, which is merely for exemplary purposes, and does not configure any limitation to the technical solution of the present disclosure.

In some embodiments, the at least one graphite sheet further includes: a third graphite sheet 203. The third graphite sheet 203 is located on a side of the line part 302 of the first flexible printed circuit 3b away from the drive substrate 101. The third graphite sheet 203 includes a first portion 2031 and a second portion 2032 connected with each other. The first portion 2031 of the third graphite sheet 203 covers at least partially a side surface of the line part 302 of the first flexible printed circuit 3b away from the drive substrate 101. The second portion 2032 of the third graphite sheet 203 is connected to the second graphite sheet 202.

In the existing art, the line part 302 of the first flexible printed circuit 3b is provided with a chip 4, which will generate a large amount of heat during operation, resulting in a relatively high temperature on the line part 302 of the first flexible printed circuit 3b, and when the heat on the line part 302 of the first flexible printed circuit 3b is transferred to the drive substrate 101, local high temperature will also occur on the drive substrate 101. To effectively improve the above technical problem, a third graphite sheet 203 is provided in an embodiment of the present disclosure to cover at least partially a side surface of the line part 302 of the first flexible printed circuit 3b away from the drive substrate 101, and to be further connected to the second graphite sheet 202. Therefore, part of the heat on the line part 302 of the first flexible printed circuit 3b can be transferred to the second graphite sheet 202 through the third graphite sheet 203, to effectively reduce the temperature at the line part 302 of the first flexible printed circuit 3b, and thus alleviate the problem of local high temperature of the drive substrate 101 caused by the heat on the line part 302 of the first flexible printed circuit 3b transferred to the drive substrate 101, which is beneficial to uniform temperature distribution on the display panel.

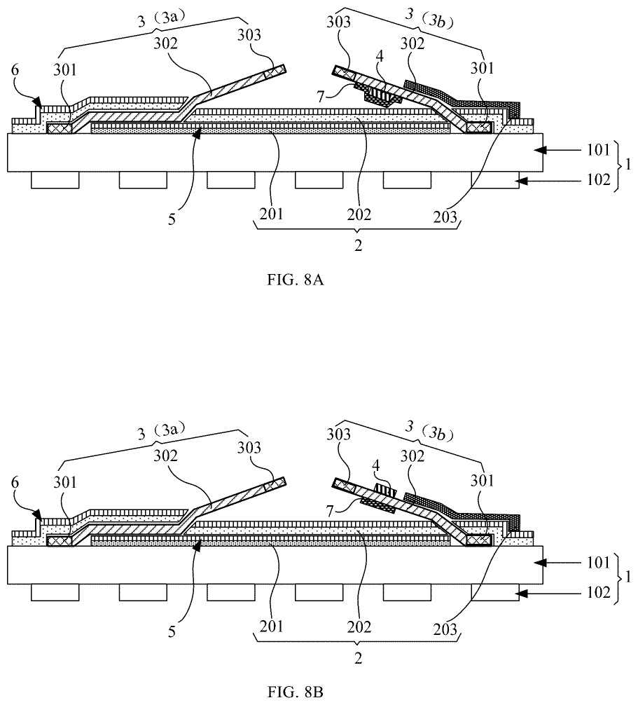

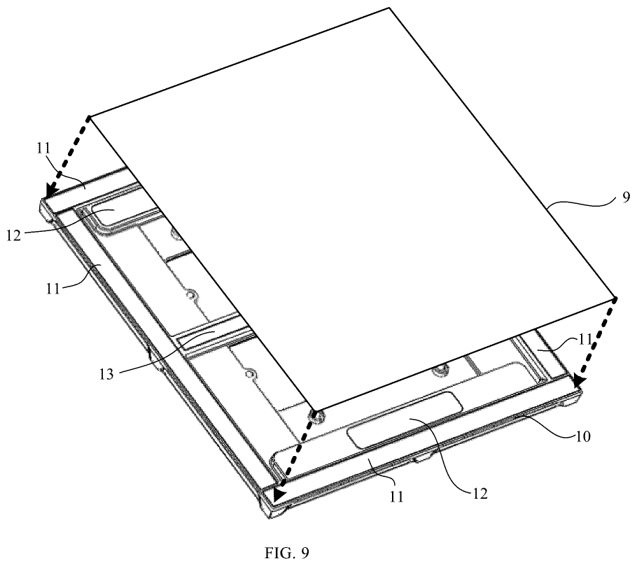

FIG. 8A is a schematic structural diagram of a thermal insulation structure on a first flexible printed circuit according to an embodiment of the present disclosure. FIG. 8B is another schematic structural diagram of a thermal insulation structure on a first flexible printed circuit according to an embodiment of the present disclosure. As shown in FIGS. 8A and 8B, in some embodiments, a side surface of the line part 302 of the first flexible printed circuit 3b packaged with the chip 4 and facing the drive substrate 101 is provided with a thermal insulation structure 7 corresponding to the chip 4. An orthographic projection of the thermal insulation structure 7 on the line part 302 of the first flexible printed circuit 3b is overlapped with an orthographic projection of the corresponding chip 4 on the line part 302 of the first flexible printed circuit 3b.

In the embodiments of the present disclosure, by providing the thermal insulation structure 7 on the side surface of the first flexible printed circuit 3b facing the drive substrate 101, heat transfer from the region packaged with the chip 4 on the line part 302 of the first flexible printed circuit 3b to the drive substrate 101 can be effectively blocked, so that the problem of high temperature on the drive substrate 101 due to heat generation of the chip 4 can be effectively solved.

In some embodiments, the orthographic projection of the thermal insulation structure 7 on the line part 302 of the first flexible printed circuit 3b completely covers the orthographic projection of the corresponding chip 4 on the line part 302 of the first flexible printed circuit 3b. With such a design, the thermal insulation effect can be favorably improved.

In some embodiments, the thermal insulation structure 7 is a thermal insulation tape.

In some embodiments, the chip 4 and the thermal insulation structure 7 may be both located on the side surface of the line part 302 of the first flexible printed circuit 3b facing the drive substrate 101 (as shown in FIG. 8A). In other embodiments, the thermal insulation structure 7 is located on the side surface of the line part 302 of the first flexible printed circuit 3b facing the drive substrate 101, while the chip 4 is located on the side surface of the line part 302 of the first flexible printed circuit 3b facing away from the drive substrate 101 (as shown in FIG. 8B). Both of these situations are intended to be within the scope of the present disclosure.

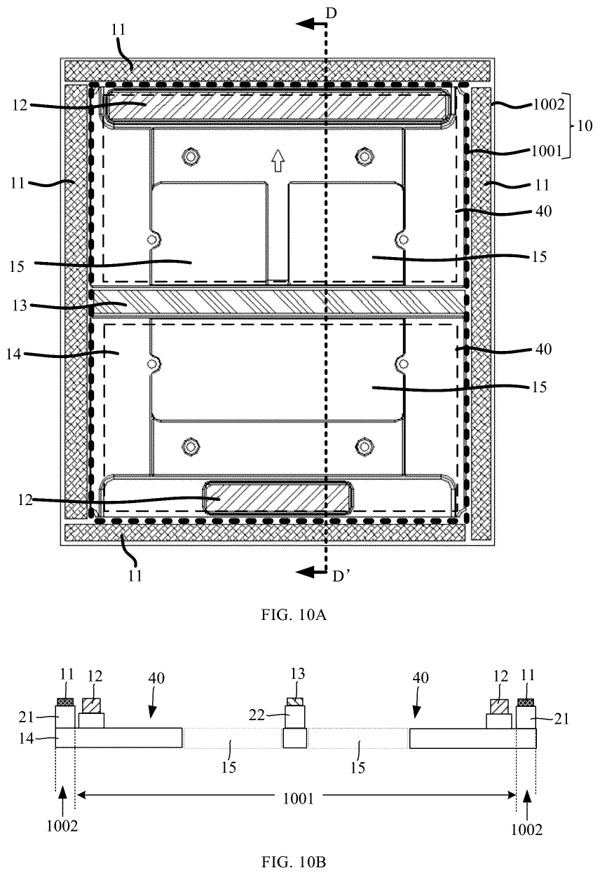

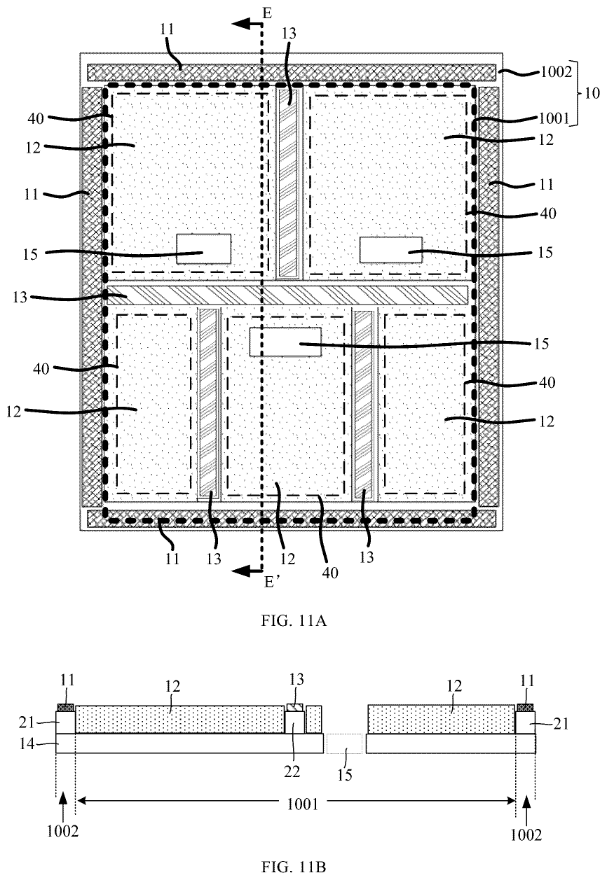

Based on the same inventive concept, an embodiment of the present disclosure further provides a display panel subassembly. FIG. 9 is a schematic structural diagram of a display panel subassembly according to an embodiment of the present disclosure. FIG. 10A is a schematic top view of a fixing frame according to an embodiment of the present disclosure. FIG. 10B is a schematic sectional view taken along line D-D′ of FIG. 10A. FIG. 11A is a schematic top view of a fixing frame according to an embodiment of the present disclosure. FIG. 11B is a schematic sectional view taken along line E-E′ of FIG. 11A. As shown in FIGS. 9 to 11B, the display panel subassembly includes a fixing frame 10, and at least one display panel 9 born on the fixing frame 10. The display panel 9 may be the display panel 9 according to any embodiment described above. For the related description of the display panel 9, reference may be made to the contents in the foregoing embodiments, and details are not repeated here.

It should be noted that FIG. 9 merely illustrates a case where one display panel 9 is born on the fixing frame 10, which is merely for exemplary purposes, and does not configure any limitation to the technical solution of the present disclosure.

In some embodiments, the fixing frame 10 includes: at least one bearing region corresponding to the at least one display panel 9 one by one. The display panel 9 is located in the corresponding bearing region. The bearing region includes: a second central region 1001, and a second peripheral region 1002 surrounding the second central region 1001. At least a portion of the fixing frame 10 in the second peripheral region 1002 is connected to the corresponding display panel 9 through a corresponding first connection structure 11. At least a portion of the fixing frame 10 in the second peripheral region 1002 is connected to the corresponding display panel 9 through a corresponding second connection structure 12. In a direction perpendicular to a plane where the drive substrate 101 is located, the second connection structure 12 has a heat conductivity higher than the first connection structure 11.

In an embodiment of the present disclosure, an orthographic projection of the second peripheral region 1002 of the fixing frame 10 on the drive substrate 101 is located in the first peripheral region 101b of the drive substrate 101 and on a side of the bonding region 103 away from the first central region 101a (i.e., a position on the drive substrate close to an edge, also referred to as an edge region of the drive substrate 101). An orthographic projection of the second central region 1001 of the fixing frame 10 on the drive substrate 101 covers the first central region 101a and the bonding region 103 of the drive substrate 101.

In an embodiment of the present disclosure, the fixing frame 10 may be an aluminum frame. The first connection structure 11 and the second connection structure 12 may connect the display panel 9 with the fixing frame 10, so that the display panel 9 can conduct heat to the fixing frame 10 through the first connection structure 11 and the second connection structure 12 to achieve heat dissipation, thereby effectively reducing the temperature of the display panel 9.

For a single display panel 9, the edge region of the drive substrate 101 in the display panel 9 generally has a temperature slightly lower than other positions (e.g., the bonding region 103 and the first central region 101a), so that the edge region of the drive substrate 101 has a lower heat dissipation requirement than other positions (e.g., the bonding region 103 and the first central region 101a), and sometimes the edge region of the drive substrate 101 even does not need any heat dissipation treatment at all.

In an embodiment of the present disclosure, the first connection structure 11 connects an edge region of the drive substrate 101 and the second peripheral region 1002 of the fixing frame 10. The second connection structure 12 connects a non-edge region of the drive substrate 101 and the second central region 1001 of the fixing frame 10. A heat conductivity of the first connection structure 11 in the longitudinal direction is designed to be smaller than the heat conductivity of the second connection structure 12 in the longitudinal direction, so as to match the heat dissipation requirements at different positions of the drive substrate 101, thereby effectively ensuring the uniform temperature distribution over the display panel 9 while satisfying the heat dissipation requirement of the drive substrate 101.

In some embodiments, an orthographic projection of the second connection structure 12 on the drive substrate 101 covers the bonding region 103. On the side of the drive substrate 101 facing away from the light-emitting elements 102, significant heat generation may occur at the bonding terminals within the bonding region 103, and therefore, the bonding region 103 has a higher heat dissipation requirement. In an embodiment of the present disclosure, the second connection structure 12 may be used to connect the bonding region 103 of the display panel 9 with the fixing frame 10, thereby effectively improving the heat dissipation performance of the bonding region 103.

In some embodiments, the fixing frame 10 includes: a bottom plate 11 and a first support structure 21 on a side of the bottom plate 11 facing the display panel 9. The first support structure 21 is located in the second peripheral region 1002. The first support structure 21 is connected to the display panel 9 through the first connection structure 11. At least a portion of the bottom plate 11 in the second central region 1001 is connected to the display panel 9 through the second connection structure 12. In an embodiment of the present disclosure, the first support structure 21 is configured to support an edge region of the display panel 9.

In some embodiments, the fixing frame 10 further includes: a second support structure 22 on a side of the bottom plate 11 facing the display panel 9. The second support structure 22 is connected to the display panel 9 through the third connection structure 13. In a direction perpendicular to a plane where the drive substrate 101 is located, the third connection structure 13 has a heat conductivity higher than or equal to the first connection structure 11. In an embodiment of the present disclosure, the second support structure 22 is configured to support a central region of the display panel 9, and the first support structure 21 and the second support structure 22 may cooperate to stably support the whole display panel 9.

When the second support structure 2 and the third connection structure 13 are provided, the central region of the display panel 9 can transfer heat to the fixing frame 10 through the third connection structure 13. In some embodiments, the third connection structure 13 includes: a thermal conductive tape. The thermal conductive tape plays not only a role of connecting the display panel 9 and the second support structure 22, but also a role of heat transfer, thereby improving the heat dissipation performance of the display panel 9.

In some embodiments, the first support structure 21, the second support structure 22, and the base plate 11 enclose at least one receiving recess 40 in the second central region 1001. The at least one receiving recess 40 is provided with the second connection structure 12.

As one example, referring to FIG. 10A, the first support structure 21, the second support structure 22, and the base plate 11 enclose two receiving recesses 40 in the second central region 1001. As another example, referring to FIG. 11A, the first support structure 21, the second support structure 22, and the base plate 11 enclose five receiving recesses 40 in the second central region 1001. It should be noted that the number and the specific distribution of the receiving recesses are not limited in the technical solutions of the present disclosure.

It should be noted that a circuit board (not shown) is provided on a side of the bottom plate 11 away from the display panel 9. Some holes 15 are defined in the bottom plate 11 (the bottom of some receiving recesses 40) of the fixing frame 10, so that a second conductive connection end of the flexible printed circuit 3 extends out to be connected to a connection terminal on the circuit board. When the second connection structure 12 is provided in the receiving recess 40, these holes 15 in the bottom plate 11 need to be avoided.

In some embodiments, the first connection structure 11 includes: a thermal insulation tape or a thermal conductive tape. The second connection structure 12 includes: a thermal conductive adhesive.

As a specific example, the first connection structure 11 in FIGS. 10A and 10B is a thermal insulation tape (the edge region of the drive substrate 101 does not need heat dissipation treatment), the second connection structure 12 is a thermal conductive adhesive, and the third connection structure 13 is a thermal conductive tape.

As another specific example, the first connection structure 11 in FIGS. 11A and 11B is a thermal conductive tape (the edge region of the drive substrate 101 needs heat dissipation treatment), the second connection structure 12 is a thermal conductive tape, and the third connection structure 13 is a thermal conductive tape.

In some embodiments, the thermal conductive adhesive is thermal conductive silicone gel. In some embodiments, the thermal conductive adhesive has a thickness of 0.2 mm to 0.7 mm.

It should be noted that, in practical applications, the thermal conductive performance of the thermal conductive adhesive in the thickness direction can be adjusted by adjusting the thickness of the thermal conductive adhesive; and generally, a thinner thermal conductive adhesive has better thermal conductive performance in the thickness direction thereof. Based on the above principle, in practical applications, the first support structure, the second support structure and the bottom plate may be used to enclose a plurality of receiving recesses in the second central region according to actual needs, and a depth of each receiving recess can be designed according to the actual heat dissipation requirements. Since the depth of the receiving recess determines the thickness of the thermal conductive adhesive (the second connection structure) filled therein, the thermal conductive performance of the region where each receiving recess is located can be adjusted respectively by adjusting the depth of the receiving recess (the thickness of the thermal conductive adhesive) (for example, the depth of at least one receiving recess is different from the depths of other receiving recesses, so that the thickness of the thermal conductive adhesive in the at least one receiving recess is different from the thicknesses of the thermal conductive adhesive in other receiving recesses), thereby satisfying different heat dissipation requirements of different regions on the display panel.

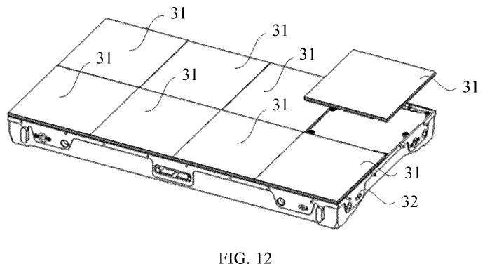

Based on the same concept, an embodiment of the present disclosure further provides a splicing display apparatus. FIG. 12 is a schematic structural diagram of a splicing display apparatus according to an embodiment of the present disclosure. As shown in FIG. 12, the splicing display apparatus includes: a plurality of display panel subassemblies 31, where at least one of the display panel subassemblies 31 is the display panel subassembly according to any of the above embodiments. For detailed description of the display panel subassembly 31, reference may be made to the contents in the foregoing embodiments, and details are not repeated here.

In some embodiments, the splicing display apparatus further includes: a bearing box 32. The bearing box 32 has a bearing surface, on which a plurality of display panel subassemblies 31 are arranged in an array along a direction parallel to the bearing surface and placed adjacent to each other. The bearing box 32 is configured to bear the plurality of the display panel subassemblies 31.

The embodiments of the present disclosure are as described above, where not all details of the embodiments are elaborated, and the present disclosure is not intended to be limited to these specific embodiments. Apparently, many modifications and variations are possible in light of the above description. The description has chosen and described these specific embodiments in detail for better illustration of the principles and practical applications of the present disclosure so that those skilled in the art can make good use of the present disclosure as well as modified applications based on the present disclosure. The present disclosure is intended to be limited only by the claims and the full scope and equivalents thereof.

What is claimed is:

1. A display panel, comprising:
a drive substrate;
a plurality of light-emitting elements on one side of the drive substrate;
a functional assembly on a side of the drive substrate away from the light-emitting elements and connected to the drive substrate; wherein
in a direction parallel to a plane where the drive substrate is located, the functional assembly has a heat conductivity higher than the drive substrate.

2. The display panel according to claim 1, wherein the drive substrate comprises: a base substrate and a plurality of driver circuits on the base substrate, wherein the light-emitting elements are connected to the corresponding driver circuits; and
in a direction parallel to a plane where the base substrate is located, the functional assembly has a heat conductivity higher than the base substrate.

3. The display panel according to claim 1, wherein the functional assembly comprises: at least one graphite sheet.

4. The display panel according to claim 3, wherein a side surface of the drive substrate away from the light-emitting elements has: a first central region and a first peripheral region surrounding the first central region, wherein the first peripheral region comprises: at least one bonding region provided with a plurality of bonding terminals;
the display panel further comprises: at least one flexible printed circuit, wherein the flexible printed circuit comprises: a first conductive connection part, a line part, and a second conductive connection part, wherein the line part is located between the first conductive connection part and the second conductive connection part, and the first conductive connection part is connected to a corresponding bonding terminal on the drive substrate; and
the at least one graphite sheet comprises: a first graphite sheet and/or second graphite sheet; wherein
the first graphite sheet is located on a side of the line part of the flexible printed circuit close to the drive substrate, an orthographic projection of the first graphite sheet on the drive substrate covers the first central region and is not overlapped with the bonding region, and the second conductive connection part of each flexible printed circuit is located on a side of the first graphite sheet away from the drive substrate; and
the second graphite sheet is located on a side of the first conductive connection part away from the drive substrate, an orthographic projection of the second graphite sheet on the drive substrate covers the bonding region and at least part of the first central region, at least part of the line part of the at least one flexible printed circuit is located between the second graphite sheet and the drive substrate, and the second conductive connection part of each flexible printed circuit is located on a side of the second graphite sheet away from the drive substrate.

5. The display panel according to claim 4, wherein a ground signal end is provided on the line part of the at least one flexible printed circuit;
a first conductive film is provided between the first graphite sheet and the line part of the flexible printed circuit, and the first conductive film is electrically connected to the ground signal end of the at least one flexible printed circuit;
and/or
a second conductive film is provided on a side of the second graphite sheet away from the drive substrate, and the second conductive film is electrically connected to the ground signal end of the at least one flexible printed circuit.

6. The display panel according to claim 5, wherein the first conductive film is provided between the first graphite sheet and the line part of the flexible printed circuit;
a portion of the first graphite sheet is connected to the second graphite sheet through the first conductive film; and
in a direction perpendicular to the plane where the drive substrate is located, the first conductive film has a heat conductivity higher than the first graphite sheet and the second graphite sheet.

7. The display panel according to claim 4, wherein the orthographic projection of the second graphite sheet on the drive substrate covers the orthographic projection of the first graphite sheet on the drive substrate.

8. The display panel according to claim 4, wherein the at least one flexible printed circuit comprises: at least one first flexible printed circuit and at least one second flexible printed circuit, wherein a line part of the first flexible printed circuit is provided with a chip, while a line part of the second flexible printed circuit is not provided with a chip; and
at least part of the line part of the second flexible printed circuit is located between the first graphite sheet and the second graphite sheet, and the line part of the first flexible printed circuit is located on a side of the second graphite sheet away from the first graphite sheet.

9. The display panel according to claim 8, wherein the at least one graphite sheet further comprises: a third graphite sheet;
the third graphite sheet is located on a side of the line part of the first flexible printed circuit away from the drive substrate, and the third graphite sheet comprises a first portion and a second portion connected with each other, and
the first portion of the third graphite sheet covers at least partially a side surface of the line part of the first flexible printed circuit away from the drive substrate, and the second portion of the third graphite sheet is connected to the second graphite sheet.

10. The display panel according to claim 4, wherein the at least one flexible printed circuit comprises: at least one first flexible printed circuit provided with a chip on a line part;
a thermal insulation structure corresponding to the chip is provided on a side surface of the line part of the first flexible printed circuit facing the drive substrate, and an orthographic projection of the thermal insulation structure on the line part of the first flexible printed circuit is overlapped with an orthographic projection of the corresponding chip on the line part of the first flexible printed circuit.

11. A display panel subassembly, comprising: a fixing frame, and at least one display panel according to claim 1; wherein
the fixing frame is configured to bear the display panel.

12. The display panel subassembly according to claim 11, wherein the fixing frame comprises at least one bearing region corresponding to the at least one display panel one by one, wherein the display panel is located in the corresponding bearing region, and the bearing region comprises: a second central region and a second peripheral region surrounding the second central region;
at least a portion of the fixing frame in the second peripheral region is connected to the corresponding display panel through a corresponding first connection structure, and at least a portion of the fixing frame in the second peripheral region is connected to the corresponding display panel through a corresponding second connection structure; and
in a direction perpendicular to a plane where the drive substrate is located, the second connection structure has a heat conductivity higher than the first connection structure.

13. The display panel subassembly according to claim 12, wherein an orthographic projection of the second connection structure on the drive substrate covers the bonding region.

14. The display panel subassembly according to claim 12, wherein the fixing frame comprises a bottom plate and a first support structure on a side of the bottom plate facing the display panel, wherein the first support structure is located in the second peripheral region;
the first support structure is connected to the display panel through the first connection structure; and
at least a portion of the bottom plate in the second central region is connected to the display panel through the second connection structure.

15. The display panel subassembly according to claim 14, wherein the fixing frame further comprises: a second support structure on a side of the bottom plate facing the display panel, wherein the second support structure is connected to the display panel through a third connection structure; and
in the direction perpendicular to the plane where the drive substrate is located, the third connection structure has a heat conductivity higher than or equal to the first connection structure.

16. The display panel subassembly according to claim 15, wherein the third connection structure comprises: a thermal conductive tape.

17. The display panel subassembly according to claim 15, wherein the first support structure, the second support structure and the bottom plate enclose at least one receiving recess in the second central region, wherein the at least one receiving recess is provided with the second connection structure.

18. The display panel subassembly according to claim 12, wherein the first connection structure comprises: a thermal insulation tape or a thermal conductive tape; and
the second connection structure comprises: a thermal conductive adhesive.

19. The display panel subassembly according to claim 18, wherein the thermal conductive adhesive has a thickness of 0.2 mm to 0.7 mm.

20. A splicing display apparatus, comprising: a bearing box and a plurality of display panel subassemblies; wherein
the bearing box is configured to bear the plurality of the display panel subassemblies; and
at least one of the display panel subassemblies is the display panel subassembly according to claim 11.
